(19) United States
(12) Patent Application Publication
(10) Pub. No.: US 2011/0074244 A1
(43) Pub. Date: Mar. 31, 2011

(54) Ultrasonic probe

(75) Inventor: Atsushi Osawa, Kanagawa (JP)

(73) Assignee: FUJIFILM Corporation, Tokyo (JP)

(21) Appl. No.: 12/923,362

(22) Filed: Sep. 16, 2010

(30) Foreign Application Priority Data
Sep. 30, 2009 (JP) 2009-227545

(51) Int. Cl. H01L 41/113

(52) U.S. Cl. 310/318

(57) ABSTRACT

An ultrasonic probe has transmitting ultrasonic transducers and receiving ultrasonic transducers. The transmitting ultrasonic transducer is composed of a multilayer piezoelectric element, and the receiving ultrasonic transducer is composed of a single-layer piezoelectric element. The transmitting and receiving ultrasonic transducers are alternately arranged in an azimuth direction to form a piezoelectric element line. The single transmitting ultrasonic transducer and the single receiving ultrasonic transducer that adjoin to each other compose a single channel to transmit ultrasonic waves and receive echoes. The transmitting ultrasonic transducer is connected to a transmission circuit board on which a pulser is implemented, and the receiving ultrasonic transducer is connected to a reception circuit board on which an amplifier is implemented. The receiving ultrasonic transducer is directly connected to the amplifier without passing through a capacitance transmission line.

### BACKGROUND OF THE INVENTION

1. Field of the Invention

The present invention relates to an ultrasonic probe used in an ultrasonic diagnostic apparatus, an electronic endoscope, and the like.

2. Description Related to the Prior Art

A medical diagnosis using an ultrasonic image is widely carried out. To produce the ultrasonic image, an ultrasonic probe, which has a lot of ultrasonic transducers arranged at a distal end, is used. Each ultrasonic transducer is constituted of a backing material, a piezoelectric layer, electrodes for sandwiching the piezoelectric layer, an acoustic impedance matching layer, and an acoustic lens. The ultrasonic transducers apply ultrasonic waves to a human body to be imaged, and receive echoes from the body. By electrically processing the echoes received by the ultrasonic transducers, the ultrasonic image is obtained.

Also, an ultrasonic tomographic image can be obtained by applying the ultrasonic waves with scanning. A scanning method for taking the ultrasonic tomographic image includes a mechanical scanning method in which the ultrasonic transducers are mechanically rotated, swung, or slid, and an electronic scanning method in which the plurality of ultrasonic transducers are arranged into an array (hereinafter called ultrasonic transducer array) and which ultrasonic transducers to drive are selectively switched with an electronic switch or the like.

It is desired to improve transmission and reception sensitivity of the ultrasonic transducers to get the higher definition ultrasonic image. To increase the transmission sensitivity, it is first conceivable to increase a voltage applied to the ultrasonic transducers to enhance transmission power of the ultrasonic waves. However, in consideration of an adverse effect on the human body, a mechanical index (MI) and a thermal index (TI) define sound pressure and an amount of energy of the ultrasonic waves that are allowable to be applied to the human body. Thus, the transmission power of the ultrasonic waves cannot be increased indiscriminately.

Also, increase in the application voltage to the ultrasonic transducers causes upsizing of voltage application circuits (pulsers) and high power consumption. In a case where the ultrasonic probe contains the pulsers, the upsizing of the pulsers causes increase in size of the ultrasonic probe and impairs operatability, which is one of the most important factors of the ultrasonic probe. In addition, if the ultrasonic probe with the pulsers is of a wireless type, increase in the application voltage shortens battery life and results in inconvenience in use.

To increase the transmission power of the ultrasonic waves with restraining the application voltage to the ultrasonic transducers, it is proposed to use a multilayer piezoelectric element in the ultrasonic transducer. The multilayer piezoelectric element, however, has a problem of the reception sensitivity, because the reception sensitivity of the multilayer piezoelectric element to the echo at a certain sound pressure level is one-Nth (“N” denotes the number of layers of the multilayer piezoelectric element) of that of a single-layer piezoelectric element.

Therefore, the ultrasonic probe is proposed in which the multilayer piezoelectric elements are used for transmitting the ultrasonic waves, and the single-layer piezoelectric elements are used for receiving the echoes. For example, in Japanese Patent Laid-Open Publication No. 2000-217196, the multilayer piezoelectric element for transmitting the ultrasonic waves is disposed on an echo receiving surface of the single-layer piezoelectric element. U.S. Pat. No. 6,640,634 describes a two-dimensional arrangement of the multilayer piezoelectric elements for transmitting the ultrasonic waves and the single-layer piezoelectric elements for receiving the echoes.

However, in the Japanese Patent Laid-Open Publication No. 2000-217196, since the multilayer piezoelectric element is disposed on the single-layer piezoelectric element, the whole of the two elements substantially has the same structure as that of the single multilayer piezoelectric element. The reception sensitivity of the multilayer piezoelectric element is one-Nth of that of the single-layer piezoelectric element, as described above, and hence the reception sensitivity is not improved. The U.S. Pat. No. 6,640,634 does not obviously describe how to arrange the multilayer and single-layer piezoelectric elements for transmission and reception and by which unit the piezoelectric elements are driven.

### SUMMARY OF THE INVENTION

An object of the present invention is to provide an ultrasonic probe that has improved transmission and reception sensitivity without degrading ultrasonic image quality.

To achieve the above and other objects, an ultrasonic probe according to the present invention includes a plurality of multilayer piezoelectric elements for transmitting an ultrasonic wave, a plurality of single-layer piezoelectric elements for receiving an echo of the ultrasonic wave, and a K number of transmitting and receiving channels. The multilayer piezoelectric elements and the single-layer piezoelectric elements are alternately arranged to form a piezoelectric element line. The transmitting and receiving channels virtually partition the piezoelectric element line, and each of the transmitting and receiving channels includes at least one multilayer piezoelectric element and at least one single-layer piezoelectric element.

It is preferable that the ultrasonic probe further include a transmission circuit for actuating the multilayer piezoelectric element and generating the ultrasonic wave from the multilayer piezoelectric element, and a reception circuit for actuating the single-layer piezoelectric element and receiving the echo through the single-layer piezoelectric element.

The ultrasonic probe may further include a first conductor connected to an electrode of each of the multilayer piezoelectric elements, and a second conductor connected to an electrode of each of the single-layer piezoelectric elements. The first conductor extends on a first side face of each of the multilayer piezoelectric elements in a direction orthogonal to the piezoelectric element line. The second conductor extends on a second side face of each of the single-layer piezoelectric elements in a direction orthogonal to the piezoelectric element line. The second side face is opposite to the first side face.

The ultrasonic probe may further include an amplifier for amplifying a signal from each of the single-layer piezoelectric elements. The single-layer piezoelectric element is directly connected to the amplifier without passing through a capacitance transmission line.

According to the present invention, the multilayer piezoelectric element and the single-layer piezoelectric element are alternately arranged to form the piezoelectric element line. The multilayer piezoelectric element transmits the ultrasonic wave, and the single-layer piezoelectric element receives the echo. At least two piezoelectric elements adjoining to each other compose the transmitting and receiving channel. The present invention makes it possible to improve transmission sensitivity of the ultrasonic wave and reception sensitivity of the echo without degrading ultrasonic image quality.

### BRIEF DESCRIPTION OF THE DRAWINGS

For more complete understanding of the present invention, and the advantage thereof, reference is now made to the following descriptions taken in conjunction with the accompanying drawings, in which:

FIG. 1 is a perspective view of an ultrasonic diagnostic apparatus;

FIG. 2 is a perspective view of an ultrasonic transducer array;

FIG. 3 is a side view of a transmitting ultrasonic transducer;

FIG. 4 is a side view of a receiving ultrasonic transducer;

FIG. 5 is a block diagram of the ultrasonic diagnostic apparatus; and

FIG. 6 is a perspective view of an ultrasonic transducer array according to a second embodiment.

### DESCRIPTION OF THE PREFERRED EMBODIMENTS

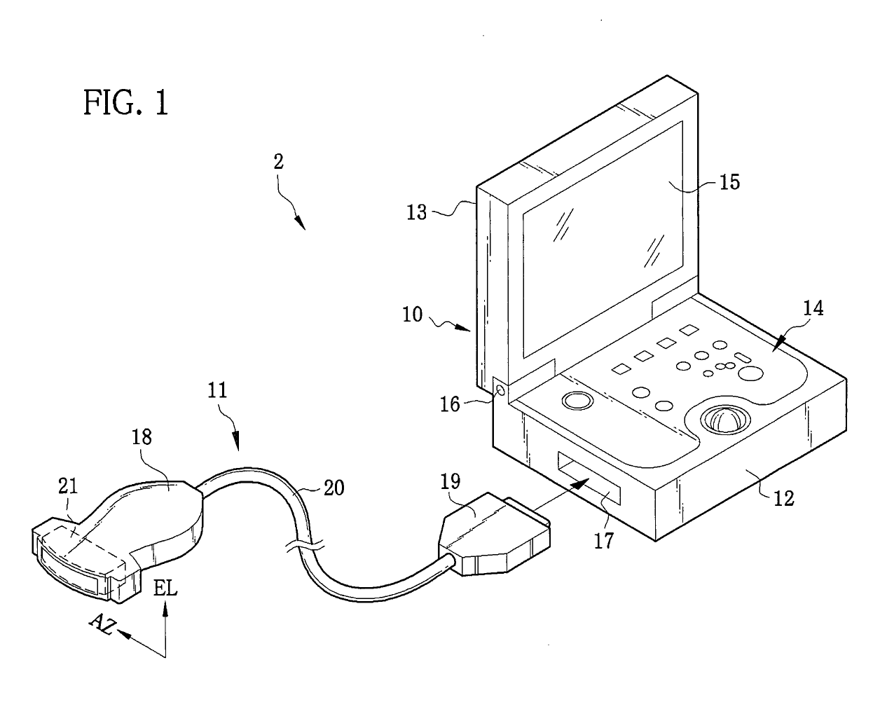

As shown in FIG. 1, an ultrasonic diagnostic apparatus 2 is constituted of a portable ultrasonic observing device 10 and an extracorporeal ultrasonic probe 11. The portable ultrasonic observing device 10 has a main body 12 and a cover 13. On a top surface of the main body 12, there is disposed an operation unit having a number of buttons and a trackball to input various operation commands to the portable ultrasonic observing device 10. Inside the cover 13, a monitor 15 is provided to display not only an ultrasonic image but also various operation screens.

The cover 13 is hinged on the main body 12, and is rotatable between an illustrated open position in which the operation unit 14 and the monitor 15 are exposed, and a closed position (not illustrated) in which the top surface of the main body 12 is faced to an inner surface of the cover 13 to cover the operation unit 14 and the monitor 15 with each other for protection. A grip (not illustrated) is attached to a side face of the main body 12 to make the portable ultrasonic observing device 10 convenient to carry about in a state of closing the main body 12 and the cover 13. In the other opposite side face of the main body 12, there is provided a probe connection portion 17 to which the ultrasonic probe 11 is detachably connected.

The ultrasonic probe 11 is constituted of a scan head 18, which a doctor holds and presses against a human body part to be imaged, a connector 19 connected to the probe connection portion 17, and a cable 20 for connecting the scan head 18 to the connector 19. An ultrasonic transducer array 21 is contained at a distal end of the scan head 18.

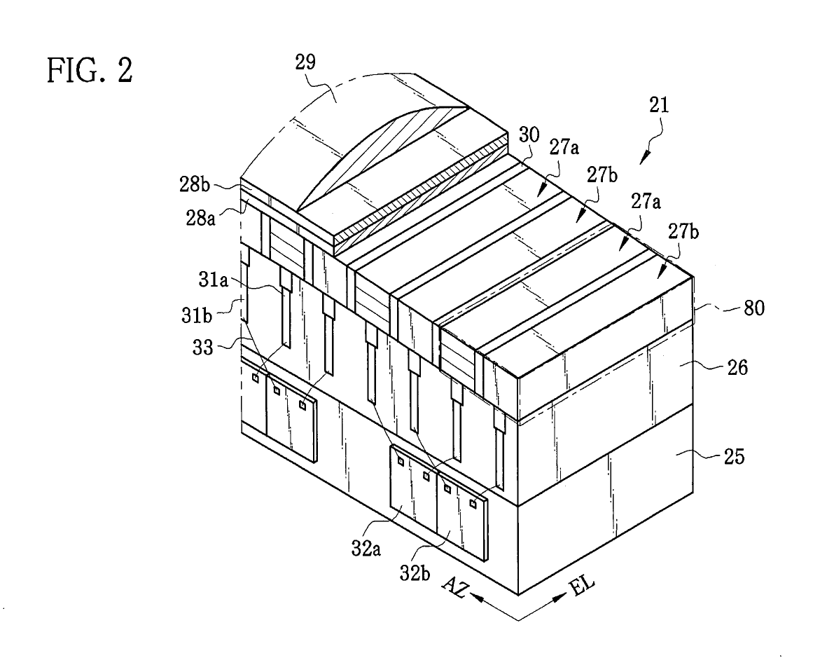

The ultrasonic transducer array 21, as shown in FIG. 2, has such structure that a backing material 26, a plurality of transmitting ultrasonic transducers 27a and a plurality of receiving ultrasonic transducers 27b, acoustic impedance matching layers 28a and 28b, and an acoustic lens 29 are stacked in this order on a mount support 25 made of a glass-epoxy resin plate or the like.

The backing material 26 is made of an epoxy resin, a silicone resin, or the like, and absorbs ultrasonic waves that are emitted from the transmitting ultrasonic transducers 27a in a direction of the mount support 25. The backing material 26 is in a gentle dome shape, and has a convex cross-section in an azimuth (AZ) direction, which is orthogonal to an elevation (EL) direction.

Each of the transmitting and receiving ultrasonic transducers 27a and 27b takes the shape of a block that is long in the EL direction. The transmitting and receiving ultrasonic transducers 27a and 27b are alternately arranged at regular intervals in the AZ direction. A filling material 30 is charged into gaps between the transmitting and receiving ultrasonic transducers 27a and 27b and around the transmitting and receiving ultrasonic transducers 27a and 27b.

The acoustic impedance matching layers 28a and 28b alleviate the difference in impedance between the ultrasonic transducer 27a or 27b and a human body. The acoustic lens 29 is made of the silicone resin or the like, and concentrates the ultrasonic waves emitted from the transmitting ultrasonic transducers 27a onto an internal body part to be imaged. The acoustic lens 29 may be omitted, and a protective layer may be provided instead of the acoustic lens 29.

A pair of a transmitting ultrasonic transducer 27a and a receiving ultrasonic transducer 27b adjoining to each other composes a single transmitting and receiving channel 80 (surrounded by alternate long and short dashed lines in FIG. 2). The ultrasonic transducer array 21 has the plurality of transmitting and receiving channels 80 arranged in the AZ direction.

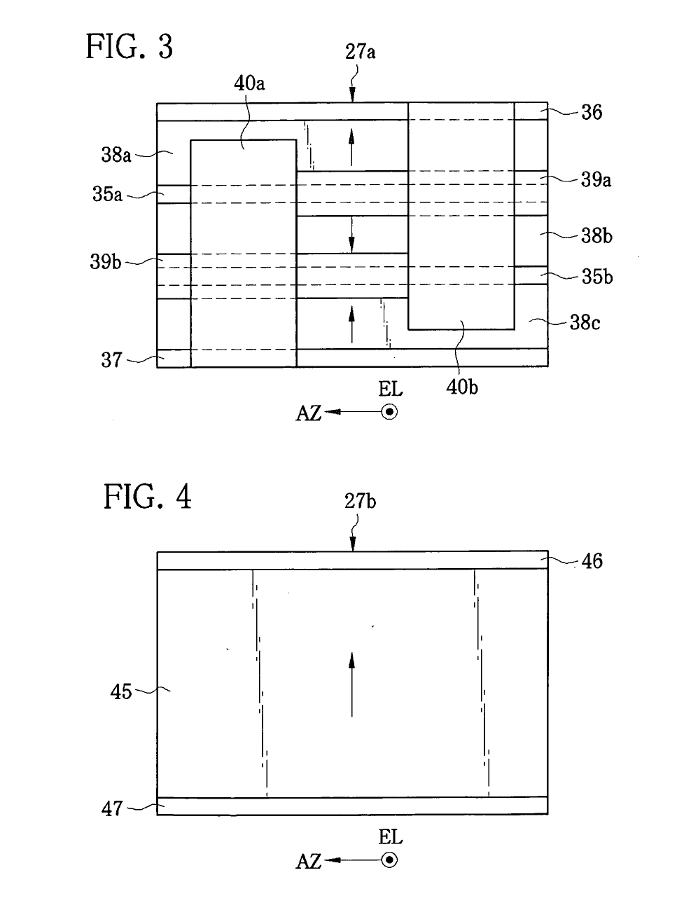

As shown in FIG. 3, the transmitting ultrasonic transducer 27a being a multilayer piezoelectric element is constituted of two internal electrodes 35a and 35b, a top electrode 36, a bottom electrode 37, three piezoelectric layers 38a to 38c, insulator layers 39a and 39b, and two conductor layers 40a and 40b. The piezoelectric layer 38a is sandwiched between the top electrode 36 and the internal electrode 35a. The piezoelectric layer 38b is sandwiched between the internal electrodes 35a and 35b, and the piezoelectric layer 38c is sandwiched between the internal electrode 35b and the bottom electrode 37. The insulator layer 39a is so formed as to expose a part of the internal electrode 35a, that is, an end face of the internal electrode 35a contacting the conductor layer 40a. In a like manner, the insulator layer 39b is so formed as to expose a part of the internal electrode 35b, that is, an end face of the internal electrode 35b contacting the conductor layer 40b. The conductor layer 40a electrically connects the internal electrode 35a to the bottom electrode 37 beyond the insulator layer 39b, and the conductor layer 40b electrically connects the internal electrode 35b to the top electrode 36 beyond the insulator layer 39a.

As shown in FIG. 4, the receiving ultrasonic transducer 27b is a single-layer piezoelectric element that has a single piezoelectric layer 45 sandwiched between a top electrode 46 and a bottom electrode 47. The top electrode 46 is disposed on the side of the acoustic impedance matching layer 28a, and the bottom electrode 47 is disposed on the side of the backing layer 26.

The piezoelectric layers 38a to 38c of the transmitting ultrasonic transducer 27a are polarized in directions illustrated by arrows, so that the piezoelectric layers next to each other are polarized in the directions opposite to each other. The piezoelectric layer 45 of the receiving ultrasonic transducer 27b is polarized in a direction from the bottom electrode 47 to the top electrode 46. The piezoelectric layers of the transmitting and receiving ultrasonic transducers 27a and 27b are made of the same material of PZT (lead zirconate titanate)-based piezoelectric ceramic.

In the transmitting ultrasonic transducer 27a, the top electrode 36 and the internal electrode 35b, which are connected by the conductor layer 40b, are grounded. The bottom electrode 37 and the internal electrode 35a, which are connected by the conductor layer 40a, are connected to a first conductor pattern 31a formed on a single side face of the backing material 26, as shown in FIG. 2. In the receiving ultrasonic transducer 27b, the top electrode 46 is grounded. The bottom electrode 47 of the receiving ultrasonic transducer 27b is connected to a second conductor pattern 31b.

Each of the first and second conductor patterns 31a and 31b downward extends on the backing material 26. The first conductor patterns 31a are connected to transmission circuit boards 32a attached to the single side face of the mount support 25, with bonding wires 33, and the second conductor patterns 31b are connected to reception circuit boards 32b in a like manner. The transmission circuit boards 32a and the reception circuit boards 32b are flexible printed circuit boards made of a polyimide or the like. The two transmitting ultrasonic transducers 27a are connected to the single transmission circuit board 32a, and the two receiving ultrasonic transducers 27b are connected to the single reception circuit board 32b. Otherwise, the three or more transmitting ultrasonic transducers 27a may be connected to the single transmission circuit board 32a, and the three or more receiving ultrasonic transducers 27b may be connected to the single reception circuit board 32b.

In manufacture of the ultrasonic transducer array 21, a green sheet method is used, for example. In this case, layers of the internal electrodes 35a and 35b are printed on only parts of piezoelectric ceramic green sheets corresponding to the transmitting ultrasonic transducers 27a, while no electrode layer is printed on parts corresponding to the receiving ultrasonic transducers 27b. Then, the printed green sheets are stacked. A stack of the green sheets manufactured as above is baked and glued on the backing material 26, and is cut into the transmitting ultrasonic transducers 27a and the receiving ultrasonic transducers 27b by dicing. Then, the insulator layers 39a and 39b and the conductor layers 40a and 40b are formed on a single side face of each of the transmitting ultrasonic transducers 27a. After that, charge of the filling material 30, attachment of the acoustic impedance matching layers 28a and 28b and the acoustic lens 29, bonding between the transmitting ultrasonic transducers 27a and the transmission circuit boards 32a and between the receiving ultrasonic transducers 27b and the reception circuit boards 32b, and the like are carried out to complete the ultrasonic transducer array 21.

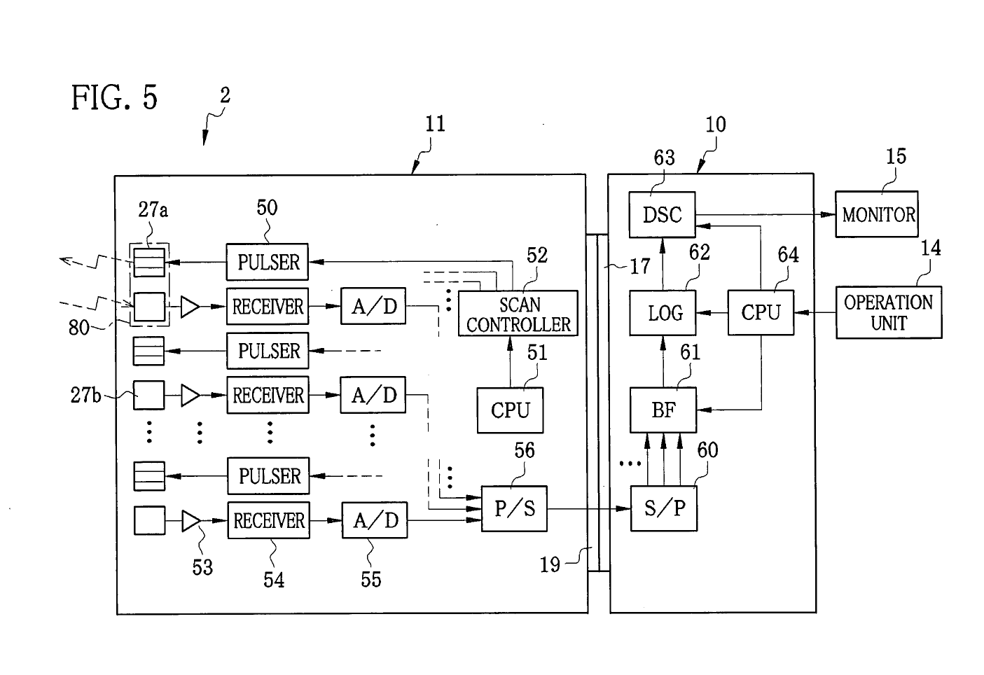

As shown in FIG. 5, pulsers 50 are connected to the transmitting ultrasonic transducers 27a on a one-by-one basis. The pulsers 50 are controlled by a scan controller 52 under the control of a CPU 51. Each pulser 50 sends exciting pulses to the corresponding transmitting ultrasonic transducer 27a to generate the ultrasonic waves. The scan controller 52 selects which pulsers to drive from among the plurality of pulsers 50, and successively switches the selection at established time intervals. To be more specific, for example, from among a hundred and twenty-eight transmitting and receiving channels, the adjoining forty-eight channels are regarded as a single block, and the pulsers 50 of the transmitting ultrasonic transducers 27a belonging to this block are driven with an arbitrary time delay. Whenever transmission and reception of the single block is completed, the scan controller 52 shifts the selection of the channels to be driven by one or some channels to configure a new block, and drives the pulsers 50 of the transmitting ultrasonic transducers 27a belonging to the new block. Thus, each of the transmitting and receiving channels is successively driven from block to block with overlapping.

To each receiving ultrasonic transducer 27b, a receiver 54 is connected through an amplifier 53. The receiver 54 is connected to an analog-to-digital converter (A/D) 55. The amplifier 53 is of a voltage feedback type or a charge storage type. The amplifier 53 amplifies a detection signal outputted as a voltage from the receiving ultrasonic transducer 27b in response to reception of the echoes. The receiver 54 receives the detection signal amplified by the amplifier 53. The A/D 55 digitizes the detection signal from the receiver 54. The receivers 54, the A/Ds 55, the amplifiers 53, and the pulsers 50 of the three channels are illustrated in FIG. 5, but are actually provided for every channel.

The pulsers 50 are implemented on the transmission circuit boards 32a. The amplifiers 53, the receivers 54, and the A/Ds 55 are implemented on the reception circuit boards 32b. Since the receiving ultrasonic transducer 27b is connected to the reception circuit board 32b via the conductor pattern 31b and the bonding wire 33, as described above, the receiving ultrasonic transducer 27b is directly connected to the amplifier 33 without passing through a capacitance transmission line such as a coaxial cable.

The A/Ds 55 are connected to a parallel-to-serial converter (P/S) 56. The P/S 56 converts parallel data of the detection signals outputted from the A/Ds 55 into serial data. This serial data is inputted to a serial-to-parallel converter (S/P) 60 of the portable ultrasonic observing device 10 through the cable 20, the connector 19, and the probe connection portion 17.

The S/P 60 converts the serial data sent from the ultrasonic probe 11 back into the parallel data. A beamformer (BF) 61 performs a phase matching operation on the parallel detection signals. A log compression and detection circuit (LOG) 62 performs a log compression operation on the detection signals outputted from the BF 61 to detect amplitude. The detection signals outputted from the LOG 62 are temporarily stored on a memory (not illustrated).

A digital scan converter (DSC) 63 converts the detection signals into a television signal under the control of a CPU 64. The television signal produced by the DSC 63 is subjected to a digital-to-analog conversion by a not-illustrated digital-to-analog converter, and is displayed as the ultrasonic image on the monitor 15.

The CPU 64 controls the operation of each part of the portable ultrasonic observing device 10. The CPU 64 actuates each part based on an operation input signal from the operation unit 14. The CPU 64 also controls a power supply to the ultrasonic probe 11.

The operation of the ultrasonic diagnostic apparatus 2 having above structure will be described. First, the connector 19 of the ultrasonic probe 11 is inserted and fixed into the probe connection portion 17 of the portable ultrasonic observing device 10, to connect the ultrasonic probe 11 to the portable ultrasonic observing device 10. Then, the portable ultrasonic observing device 10 is turned on with operation from the operation unit 14. The doctor observes the ultrasonic image displayed on the monitor 15 of the portable ultrasonic observing device 10 and carries out diagnosis, while pressing the scan head 18 of the ultrasonic probe 11 against the human body part to be imaged.

In the ultrasonic probe 11, the exciting pulses are sent from the forty-eight pulsers 50 of the single block selected by the scan controller 52 to the transmitting ultrasonic transducers 27a of the corresponding channels, and the ultrasonic waves are applied to the human body part to be imaged. The scan controller 52 successively switches driving of the pulsers 50 on a block basis, whenever the ultrasonic waves are transmitted and received. Thus, the human body part is scanned with an ultrasonic beam.

The ultrasonic waves emitted from the transmitting ultrasonic transducer 27a of one channel are reflected by the human body part, and the detection signal corresponding to the echoes is outputted from the receiving ultrasonic transducer 27b of the same channel. The detection signal from the receiving ultrasonic transducer 27b is amplified by the amplifier 53, and is received by the receiver 54, and is digitized by the A/D 55. The digital detection signals from the A/Ds 55 are converted into the serial data by the P/S 56, and the serial data is sent to the portable ultrasonic observing device 10.

In the portable ultrasonic observing device 10, the S/P 60 converts the serial data back into the parallel detection signals. Then, the detection signals are subjected to the phase matching operation by the BF 61, and the log compression operation by the LOG 62 to detect the amplitude, and then are temporarily stored on the memory.

The detection signals after the log compression and the amplitude detection are converted into the television signals by the DSC 63. The television signal produced by the DSC 63 is displayed on the monitor 15 as the ultrasonic image after the digital-to-analog conversion.

As described above, the transmitting ultrasonic transducers 27a being the multilayer piezoelectric elements and the receiving ultrasonic transducers 27b being the single-layer piezoelectric elements are alternately arranged in the AZ direction, so as to form a piezoelectric element line. The adjoining two ultrasonic transducers 27a and 27b compose the single transmitting and receiving channel, which transmits the ultrasonic waves and receives the echoes, so that it is possible to increase transmission sensitivity of the ultrasonic waves and reception sensitivity of the echoes without degrading ultrasonic image quality.

In a conventional ultrasonic probe, the two or three adjoining ultrasonic transducers compose the single channel. Taking a case where the single channel has the two ultrasonic transducers as an example, both of the two ultrasonic transducers are actuated to emit the ultrasonic waves, and signals received by both of the two ultrasonic transducers are added up to obtain the single detection signal. In the present invention, on the contrary, out of the two ultrasonic transducers composing the single channel, one of the ultrasonic transducers is used for transmitting the ultrasonic waves, and the other one is used for receiving the echoes. Therefore, it is possible to obtain the ultrasonic image that has equal azimuth resolution and image quality to those of conventional one.

Conventionally, the both of the two ultrasonic transducers composing the single channel carry out transmission and reception. In the present invention, on the contrary, one of the two ultrasonic transducers carries out the transmission, and the other one carries out the reception. According to the present invention, the size of an ultrasonic wave transmitting surface (top surface) is reduced by approximately half and transmission power is also reduced, as compared with those of the conventional one. Thus, it is necessary to increase the number of layers of the multilayer piezoelectric element, as compensation for reduction in the transmission power.

The number N of layers of the multilayer piezoelectric element satisfies the following expression (1):

N=V1/(Vn·S) (1)

Wherein, V1 represents an application voltage in the case of using the single-layer piezoelectric element for transmission of the ultrasonic waves, Vn represents an application voltage in the case of using the multilayer piezoelectric element for transmission of the ultrasonic waves, and S represents a size rate of the ultrasonic wave transmitting surface. The transmission power obtained by the application of the voltage Vn to the multilayer piezoelectric element having an N number of layers is equal to the transmission power obtained by the application of the voltage V1 to the single-layer piezoelectric element.

When the single transmitting and receiving channel is constituted of one multilayer piezoelectric element and one single-layer piezoelectric element, “S” stands at 0.5. If V1=±100 (V) and V2=±20 (V), for example, the number “N” of layers becomes 10, according to the expression (1). As is apparent from above, the number “N” of layers of the multilayer piezoelectric element is appropriately changeable in accordance with the number of the multilayer piezoelectric elements included in the single transmitting and receiving channel and performance of the used pulser (a voltage applied from the pulser to the multilayer piezoelectric element), though the multilayer piezoelectric element of the above embodiment, i.e. the transmitting ultrasonic transducer 27a has three layers just as an example.

In a case where the single transmitting and receiving channel is constituted of the multilayer piezoelectric element and the single-layer piezoelectric element, capacitance of the single-layer piezoelectric element for reception is reduced as compared with that of the conventional ultrasonic probe, and hence the detection signal outputted in response to the reception of the echoes has a relatively lower voltage level. To compensate for reduction in the voltage level, in the above embodiment, the receiving ultrasonic transducer 27b is directly connected to the amplifier without passing through a capacitance transmission line. This allows minimization of reduction in the voltage level.

Therefore, it is possible to improve the transmission sensitivity of the ultrasonic waves and the reception sensitivity of the echoes without adverse effect on the ultrasonic image quality, even if the single transmitting and receiving channel is constituted of the multilayer piezoelectric element and the single-layer piezoelectric element. Improvement in the transmission and reception sensitivity makes it possible to more accurately capture harmonics for use in harmonic imaging, which becomes a focus of attention in recent years. For example, the multilayer piezoelectric element may be used for transmitting and receiving a fundamental, and the single-layer piezoelectric element may be used for receiving the harmonics. This structure contributes to improvement in image quality in the harmonic imaging.

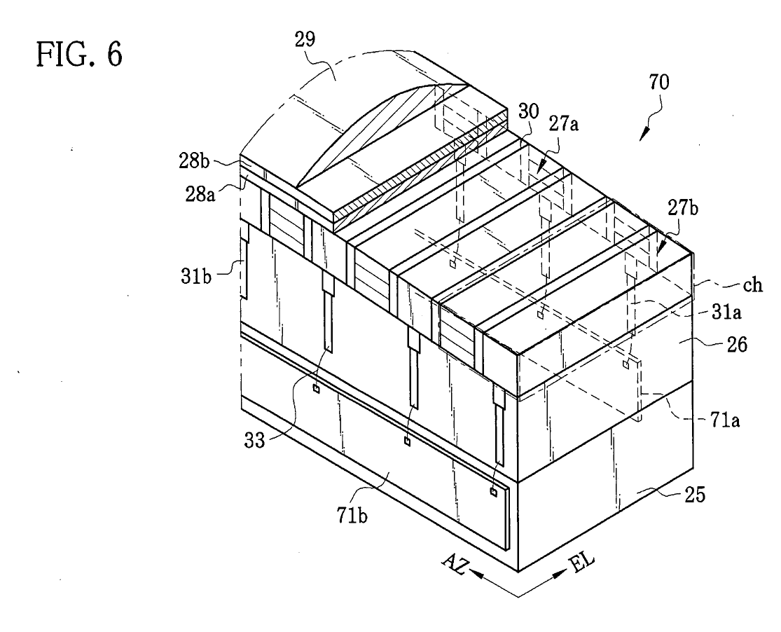

In the above embodiment, the first and second conductor patterns 31a and 31b are disposed on the single side face of the backing material, and the transmission and reception circuit boards 32a and 32b are disposed on the single side face of the mount support 25. However, in an ultrasonic transducer array 70, as shown in FIG. 6, a transmission circuit board and the first conductor patterns may be disposed on the single side face of the backing material 26 and the single side face of the mount support 25 that are orthogonal to the EL direction, while a reception circuit board and the second conductor patterns may be disposed on the other side faces thereof.

In FIG. 6, the ultrasonic transducer array 70 has similar structure to that of the ultrasonic transducer array 21 of FIG. 2, but is different therefrom in the way that the first and second conductor patterns 31a and 31b are separately formed on the opposite two side faces of the backing material 26, and a transmission circuit board 71a and a reception circuit board 71b are separately disposed on the opposite two side faces of the mount support 25. Each of the circuit boards 71a and 71b is composed of a single flexible printed circuit board that is long in the AZ direction. Use of the single long circuit board 71a or 71b eliminates the need for preparing and attaching the plurality of circuit boards as in the case of the ultrasonic transducer array 21 of FIG. 2, and hence contributes reduction in component cost and the number of manufacturing processes. Also, since the transmission circuit board 71a and the reception circuit board 71b are separately disposed on the opposite two side faces, noise occurring in one of the circuit boards 71a and 71b cannot propagate to the other. This allows stabilization of operation of the circuit boards 71a and 71b.

The conductor patterns and the circuit boards may be embedded in the backing material and the mount support. In this case, a water-cooling mechanism may be provided for the purpose of cooling components, especially absorbing heat due to a drive of the amplifiers implemented on the circuit boards. To be more specific, a conduit through which a liquid coolant such as water flows is installed inside the mount support and/or the backing material. Then, a refrigerator and a circulating pump are connected to the conduit, so that the circulating pump circulates the coolant in the conduit, while the refrigerator cools the coolant that has absorbed the heat of the amplifiers.

The above instances describe about disposition of the circuit boards on the side faces of the mount support and embedment thereof, but the disposition and the embedment may be combined. For example, the one of the circuit boards may be disposed on the side face of the mount support, and the other one may be embedded inside the mount support.

In the above embodiment, the ultrasonic probe is connected to the portable ultrasonic observing device with the cable, but the present invention is applicable to the ultrasonic probe that transmits/receives data to/from the portable ultrasonic observing device by radio. In this case, a wireless transmitting section is provided behind the P/S 56 of FIG. 5, and a wireless receiving section is provided before the S/P 60 in order to communicate the detection signal by radio. Also, the ultrasonic probe has a battery to supply electric power from the battery to each part of the ultrasonic probe.

According to the present invention, since the multilayer piezoelectric element is used for transmission of the ultrasonic waves, even if the transmitting ultrasonic transducer is driven with a relatively low voltage, high transmission sensitivity is obtained. Thus, long battery life is obtained in a battery-driven type wireless ultrasonic probe, as described above. Also, low voltage driving allows reduction in size of circuits including the pulsers, and hence contributes size reduction of the ultrasonic probe.

A multiplexer may be interpolated between the ultrasonic transducer array, and the pulsers and the receivers to selectively switch the ultrasonic transducers to be driven. Output terminals of the multiplexer are connected to all of the one hundred twenty-eight channels, and input terminals of the multiplexer are connected to forty-eight channels. With successively switching the multiplexer, each ultrasonic transducer is driven with the arbitrary delay. In this case, the forty-eight pulsers and the forty-eight receivers are enough to be prepared because the number of the pulses and the receivers corresponds to the number of channels driven at a time, and thus it is possible to further reduce the size of the ultrasonic probe. Also, scan control becomes easier, because all the scan controller has to do is to transmit a switch signal to the multiplexer.

In the above embodiment, the piezoelectric layers of the multilayer piezoelectric element and the single-layer piezoelectric element are made of the same material of the piezoelectric ceramic, but may be made of different materials. The single transmitting and receiving channel is constituted of the single transmitting ultrasonic transducer and the single receiving ultrasonic transducer, but may be constituted of three or more ultrasonic transducers including, for example, two transmitting ultrasonic transducers and one receiving ultrasonic transducer, or one transmitting ultrasonic transducer and two receiving ultrasonic transducers. Even in this case, the transmitting ultrasonic transducers being the multilayer piezoelectric elements and the receiving ultrasonic transducers being the single-layer piezoelectric elements are still alternately arranged in the AZ direction.

In the above embodiment, the so-called convex electronic scanning type extracorporeal ultrasonic probe is described, but the present invention is applicable to a linear electronic scanning type or a radial electronic scanning type of ultrasonic probe. The ultrasonic transducers are arranged in one dimension, but may be arranged in two dimensions. The present invention may be applied to an intracorporeal ultrasonic probe inserted into a forceps channel of an electronic endoscope, or an ultrasonic endoscope integrated with the electronic endoscope.

Although the present invention has been fully described by the way of the preferred embodiment thereof with reference to the accompanying drawings, various changes and modifications will be apparent to those having skill in this field. Therefore, unless otherwise these changes and modifications depart from the scope of the present invention, they should be construed as included therein.

What is claimed is:

1. An ultrasonic probe comprising:
a plurality of multilayer piezoelectric elements for transmitting an ultrasonic wave;
a plurality of single-layer piezoelectric elements for receiving an echo of the ultrasonic wave, the multilayer piezoelectric elements and the single-layer piezoelectric elements being alternately arranged to form a piezoelectric element line; and
a K number of transmitting and receiving channels for virtually partitioning the piezoelectric element line, each of the transmitting and receiving channels including at least one of the multilayer piezoelectric elements and at least one of the single-layer piezoelectric elements.

2. The ultrasonic probe according to claim 1, further comprising:
a transmission circuit for actuating the multilayer piezoelectric element and generating the ultrasonic wave from the multilayer piezoelectric element; and
a reception circuit for actuating the single-layer piezoelectric element and receiving the echo through the single-layer piezoelectric element.

3. The ultrasonic probe according to claim 1, further comprising:
a first conductor connected to an electrode of each of the multilayer piezoelectric elements, the first conductor extending on a first side face of each of the multilayer piezoelectric elements in a direction orthogonal to the piezoelectric element line; and
a second conductor connected to an electrode of each of the single-layer piezoelectric elements, the second conductor extending on a second side face of each of the single-layer piezoelectric elements in a direction orthogonal to the piezoelectric element line, the second side face being opposite to the first side face.

4. The ultrasonic probe according to claim 1, further comprising:
an amplifier for amplifying a signal from each of the single-layer piezoelectric elements, the single-layer piezoelectric element being directly connected to the amplifier without passing through a capacitance transmission line.
